(19) United States
(12) Patent Application Publication
(10) Pub. No.: US 2015/0346266 A1
(43) Pub. Date: Dec. 3, 2015

(54) SYSTEM AND METHOD FOR PULSED GROUND FAULT DETECTION AND LOCALIZATION

(71) Applicant: Eaton Corporation, Cleveland, OH (US)

(72) Inventors: Steven Andrew Dimino, Wauwatosa, WI (US); David Glenn Loucks, Coraopolis, PA (US); Robert Thomas Wolfe, Brookfield, WI (US)

(73) Assignee: Eaton Corporation, Cleveland, OH (US)

(21) Appl. No.: 14/291,161

(22) Filed: May 30, 2014

(51) Int. Cl. G01R 31/08; G01R 31/02

(52) U.S. Cl. CPC G01R 31/088; G01R 31/025; G01R 31/086

(57) ABSTRACT

A system for locating a ground fault in a high resistance grounded (HRG) power distribution system includes a pulsing circuit configured to introduce a pulse current into the distribution system and current sensors adapted to monitor three-phase current signals present on conductors of the distribution system, with the current sensors positioned on a number of distribution networks included in the HRG power distribution system and at a protective device included on each respective distribution network. A processor associated with each protective device receives signals from the current sensors for identifying a location of the ground fault in the HRG power distribution system, with the processor associated with each protective device receiving measurements of the three-phase current signals from the current sensors over a plurality of cycles and identifying a pattern of interest in the three-phase current signals across the plurality of cycles in order to detect a ground fault.

### BACKGROUND OF THE INVENTION

The present invention relates generally to power distribution systems and, more particularly, to a system and method for detecting and localizing high resistance ground faults in a power distribution system using a pulsed detection algorithm.

A ground fault is an undesirable condition in an electrical system in which electrical current flows to the ground. A ground fault happens when the electrical current in a distribution or transmission network leaks outside of its intended flow path. Distribution and transmission networks are generally protected against faults in such a way that a faulty component or transmission line is automatically disconnected with the aid of an associated circuit breaker.

Various grounding methods may be used for power distribution systems, such that such systems may generally be described as solidly grounded systems, ungrounded systems, high resistance grounded systems, or low resistance grounded systems. With solidly grounded systems, the fault currents are large and faulted devices, like motors must be taken off-line immediately. In ungrounded systems, high fault currents typically do not occur after the first ground fault but may be present on subsequent faults that create phase-to-phase shorts. High transient line-to-ground overvoltages are also a potential issue with ungrounded systems. Resistance grounded systems (high and low) limit fault current and have become common in industrial process control where minimizing down time is a key goal. However, for each system, it is recognized that a different level and technique is required for ground fault sensing.

In solidly grounded systems, ground fault currents are very large and the primary measure of efficacy is time-to-trip. Trip times are directed by UL1053. A typical device can use the residual sum method with minimum current levels at 10-30% of full load amperes (FLA). These devices also require a ground fault trip inhibit level to prevent the overload from attempting to break ground currents that exceed the rating of the interrupting device. Such an inhibit function would be important for devices with low interrupting ratings, such as a motor starter. Many devices used to protect solidly-grounded systems provide a separate shunt-trip output so that another device in the current path capable of interrupting the high fault current, such as a circuit breaker, can interrupt the fault current instead of the contactor. Solidly grounded systems are the most common type of industrial installation.

In ungrounded systems, the path for ground current is through the capacitance in the cabling. This means that very low ground currents may be present in the case of a single fault. Sensing and locating the ground fault may require highly sensitive devices. Because the ground currents are essentially negligible, ungrounded systems have the advantage of being able to remain in service if one phase is faulted to ground. However, suitable ground detection must be provided to alarm (not trip) on this condition and, since the fault current is so low, current monitoring relays may not be effective on ungrounded systems unless they are extremely sensitive (requiring external current transformers).

High resistance grounded (HRG) systems have become common since they limit fault current—allowing systems to remain in service with a single ground fault—with currents typically being limited to less than 5 amps. Locating the fault is typically done with a hand-held ammeter sometimes combined with a pulsing circuit. Protective devices like Motor Protection Relays (MPR) that are sensitive enough to locate the fault (with and without pulsing) are desired. Realistically, an MPR may be able to detect fault currents with the internal summation method through NEMA size 3, but a zero sequence current transformer is required for larger applications. This requires the ground fault sensing device to have current measurement capabilities equivalent to revenue meters when the residual sum method is used.

By sizing the resistor such that a higher ground fault current—typically 200-800 A—flows during a ground fault, a low-resistance grounded system is created. The ground fault current is limited, but is of high enough magnitude to require its removal from the system as quickly as possible. The low-resistance grounding arrangement is typically used in medium voltage systems, which have only three-wire loads. The low-resistance grounding arrangement is generally less expensive than the high resistance grounding arrangement but more expensive than a solidly grounded system.

With respect specifically to HRG systems, it is recognized that the use of a hand-held ammeter to trace a high resistance ground fault (HRGF) in power systems does not provide an ideal solution for locating the fault. That is, in employing a hand-held ammeter to trace a ground fault in a power system, the ammeter must typically be placed such that it encircles all the conductors at a selected measurement point in the power system in order to indicate whether the measurement point is between the grounding impedance and location of the ground fault. While this provides accurate results, such manual positioning of the ammeter at multiple locations, moving from one point to another in the power system until the fault is located, this process is recognized as being time consuming and labor-intensive.

Other automated techniques for tracing a HRGF in high resistance grounded power systems have been developed more recently that obviate the need for a hand-held ammeter. One such technique uses processors to calculate relationships between current and voltage phase angles present in a power distribution system, with the technique reading the current and voltage, calculating the zero sequence current (after subtracting the capacitive charging current), then running this signal through a low pass analog filter in order to determine a change in the RMS amplitude value of the zero sequence current before and after pulsing—with a faulted feeder being identified if the magnitude of the output of the filter exceeds some pre-determined value. While such a technique does provide for the tracing of a ground fault in a high resistance grounded power system without use of a hand-held ammeter, the technique requires the use of voltage sensors due to the need the extra for sensitivity to differentiate between the capacitive charging current and the actual pulsing ground current, therefore adding cost to the system. Additionally, the technique is very complex and computationally intensive, while at the same time, certain elements are not robust in being able to detect a fault.

It would therefore be desirable to provide a system and method that provides a computationally efficient approach to detect an HRGF in a three-phase power distribution system and identify the HRGF location, without the use of a hand-held ammeter.

### BRIEF DESCRIPTION OF THE INVENTION

Embodiments of the present invention provide a system and method for detecting HRGFs in a power distribution system and identifying the location of such ground faults.

In accordance with one aspect of the invention, a system for locating a ground fault in a high resistance grounded power distribution system includes a pulsing circuit configured to introduce a pulse current into the distribution system and a plurality of current sensors adapted to monitor three-phase current signals present on conductors of the distribution system, wherein the plurality of current sensors are positioned on a number of distribution networks included in the high resistance grounded power distribution system and at a protective device included on each respective distribution network. The system also includes a processor associated with each protective device and operably connected to the current sensors thereat to receive signals from the current sensors for identifying a location of the ground fault in the high resistance grounded power distribution system, wherein the processor associated with each protective device is programmed to receive measurements of the three-phase current signals from the current sensors over a plurality of cycles and identify a pattern of interest in the three-phase current signals across the plurality of cycles in order to detect a ground fault.

In accordance with another aspect of the invention, a method for detecting a ground fault in a high resistance grounded power distribution system includes providing a protective device on each of a number of distribution networks in the high resistance grounded power distribution system, each distribution network having a three-phase load connected thereto. The method also includes providing current sensors at each protective device, introducing a pulse current into the high resistance grounded power distribution system via a pulsing circuit, monitoring current at each protective device via the current sensors to collect three-phase current data, and inputting the current data to a processor associated with each protective device to identify and localize a ground fault in the high resistance grounded power distribution system. Identifying and localizing the ground fault further includes determining a root mean square (RMS) current from the collected three-phase current data, identifying step changes in the RMS current across the plurality of cycles to detect pulse current present at the respective protective device, and localizing a ground fault in the high resistance grounded power distribution system to a respective distribution network based on the detection of the pulse current.

In accordance with yet another aspect of the invention, a system for detecting a ground fault in a high resistance grounded (HRG) power distribution system includes a protective device connected to each of one or more distribution networks in the HRG power distribution system, the protective device providing monitoring of its associated distribution network and protection to a load connected thereto. The system also includes a plurality of current sensors in operable communication with the protective device to measure three-phase current on the distribution network, the three-phase current comprising a ground current and capacitive system charging current. The protective device includes a processor programmed to receive measurements of the three-phase current signals from the current sensors over a plurality of cycles, determine a root mean square (RMS) current based on the three-phase current signals received from the current sensors, and analyze the RMS current across a plurality of cycles to identify a pattern of interest indicative of a high resistance ground fault.

Various other features and advantages of the present invention will be made apparent from the following detailed description and the drawings.

### BRIEF DESCRIPTION OF THE DRAWINGS

The drawings illustrate preferred embodiments presently contemplated for carrying out the invention.

In the drawings:

FIG. 1 a diagrammatical view of a system for locating a ground fault in a high resistance grounded (HRG) power distribution system, according to an embodiment of the invention.

FIG. 2 is a graph illustrating a pulsed square waveform root mean square (RMS) current on an oscillographic ground current waveform, illustrative of a presence of a HRGF.

FIG. 3 is a graph illustrating a thresholded square current waveform and a trace of an Output Flag value, both generated by a pulse detection algorithm, according to an embodiment of the invention.

FIG. 4 is a flowchart illustrating a technique for detection of a HRG ground fault in the power distribution system of FIG. 1, according to an embodiment of the invention.

### DETAILED DESCRIPTION

Embodiments of the invention relate to a system and method for detecting and locating HRGFs in a power distribution system and protecting the power distribution system from such ground faults upon detection thereof. The system and method for detecting and locating these HRGFs may be utilized in power distribution systems encompassing a plurality of structures and control schemes, and thus application of the invention is not meant to be limited strictly to power distribution systems having the specific structure described here below.

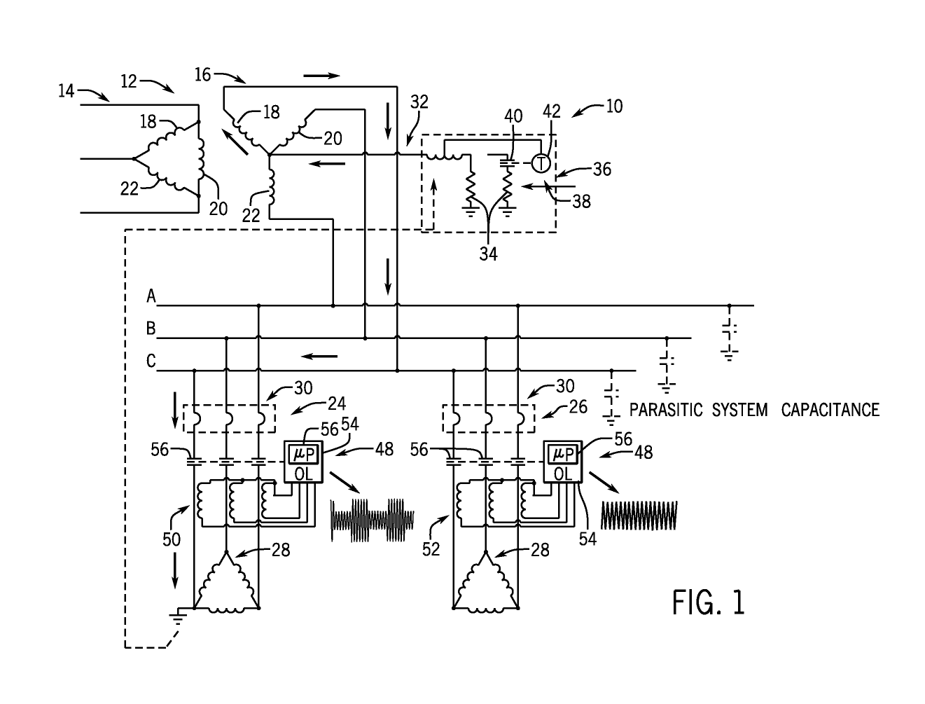

Referring first to FIG. 1, according to an exemplary embodiment of the invention, a power distribution system 10 is provided with which embodiments of the invention may be implemented. The system 10 includes a power transformer 12 having an input side 14 and an output side 16. The power transformer 12 comprises three phases, i.e., a first phase 18, a second phase 20, and a third phase 22 that are coupled, in the example of FIG. 1, per the angle of the primary and secondary windings. That is, the third phase 22 on the primary has the same angle as what is shown as the first phase 18 on the secondary. Likewise, the first phase 18 on the primary is coupled with the second phase 20 shown on the secondary, and the second phase 20 on the primary is coupled with what is shown as the third phase 22 on the secondary.

The three phases 18, 20, 22 of the power transformer 12 are coupled to a plurality of three-phase distribution networks 24, 26. While only two distribution networks 24, 26 are illustrated in FIG. 1, it is recognized that a greater number of distribution networks could be included in the power distribution system 10. A load 28, such an induction motor for example, is connected to each distribution network 24, 26 to receive three phase power therefrom. Each distribution network 24, 26 is also provided with a circuit breaker 30, as well as other protective devices, where appropriate.

In the embodiment of FIG. 1, power distribution system 10 is provided as a three phase high resistance grounded (HRG) power distribution system, where a neutral line 32 at the output side 16 of the power transformer 12 is grounded via one or more grounding resistors 34 included in a grounding device 36. The grounding resistors 34 are configured to reduce the ground fault current, so that the system 10 can remain in operation while a ground fault is being located. That is, when there is an occurrence of a ground fault in the system 10, the grounding resistors 34 limit the fault current, resulting in the collapse of the phase-to-ground voltage in the faulted phase.

The grounding device 36 also includes a test signal generator 38 (i.e., “pulsing circuit”) that is incorporated into grounding device 36 and is configured to introduce a test signal into the power distribution system 10. The test signal is a pulse current signal generated at desired intervals, at a frequency of 0.5 to 10 Hz for example. In the illustrated embodiment, the pulsing circuit 38 includes a switch 40 (i.e., contacts) and associated controller 42 provided to generate a pulse current signal in the power distribution system 10. One of the grounding resistors 34 is periodically partially shorted by closing the switch 40 (via controller 42.) to generate the pulse signal at desired intervals. According to embodiments of the invention, the pulsing circuit 38 may be caused to introduce the pulse signal in various manners, such as being manually set to introduce the pulse signal upon detection of a ground fault or automatically introducing the pulse signal upon detection of a ground fault. The duration for which the pulse signal is added may also be controlled according to various control schemes that will not be discussed in further detail herein, as they are not critical to the present invention.

As further shown in FIG. 1, a ground fault locating system 48 is provided for the high resistance grounded power distribution system 10. The ground fault locating system 48 includes a plurality of current sensors 50, 52 coupled to the three phase power distribution system 10, for measuring values of the instantaneous three-phase current. In one exemplary embodiment, such as where contactors and/or control/protection devices associated with the loads 28 on power distribution networks 24, 26 are NEMA size 4 or 5, the current sensors 50, 52 may be current transformers (CTs) configured to generate feedback signals representative of instantaneous current through each phase. Other types of current sensors may, of course, be employed.

The current sensors 50, 52 are positioned on respective distribution networks 24, 26 and are located on the distribution networks to measure three-phase current signals at a protection device 54 connected thereto. According to various embodiments, the protection device 54 may be in the form of a protection relay, circuit breaker trip unit, metering device, IED (intelligent electronic device), RTU, or protective relay that provide protection to a connected load, such as a motor for example. Thus, while specific reference is made here-after to the protection device being a “motor protection relay”, it is to be understood that other protection devices—for motors or other loads—are considered to be within the scope of the invention. As shown in FIG. 1, the motor protection relay units 54 are included in the ground fault locating system 48 and operate as highly configurable motor, load and line protection devices with power monitoring, diagnostics and flexible communications capabilities—including controlling contactors 56 on the distribution networks 24, 26. The current signals generated/measured by current sensors 50, 52 are provided to a processor 56 that is incorporated into the motor protection relay unit 54. While processor 56 is shown and described as being incorporated into motor protection relay unit 54, it is recognized that the processor 56 could also be a stand-alone device/unit or incorporated/form another device, including a microprocessor based module, an application-specific or general purpose computer, programmable logic controller, or a logical module. The processor 56 may provide for an analog-to-digital conversion of the signals received from the current sensors 50, 52, digitally filter the signals received from the current sensors 50, 52, and perform computations for identifying the presence of a ground fault indicative of a HRGF condition in the power distribution system 10, as described below.

In operation, the processor 56 of each motor protection relay unit 54 receives signals from its associated current sensors 50, 52 regarding the measured three-phase current present on the distribution network 24, 26 to which the current sensors are attached—i.e., at the motor protection relay unit. Depending on the location of the ground fault in the power distribution system 10, the current measured by the current sensors 50, 52 may be a measure of just the normally occurring system “capacitive system charging currents” (plus any nominal additional current that may be present, i.e., a “no ground fault” nominal current) or may be a measure of the capacitive system charging currents and a ground current present on one of the distribution networks 24, 26 resulting from a ground fault located thereon. As previously mentioned above, the pulsing circuit 38 of the grounding device 36 functions to introduce a pulsing signal into the power distribution system 10 upon occurrence of a ground fault. This pulsing current signal is introduced periodically (e.g., frequency of 1 Hz) and serves to increase the ground fault current present in the power distribution system 10—with the increase of the ground current being measureable by the current sensors 50, 52 when present. According to embodiments, the pulsing current signal serves to increase the ground fault by a factor of 1.5-3.0 times, with a doubling of the current being provided in an exemplary embodiment.

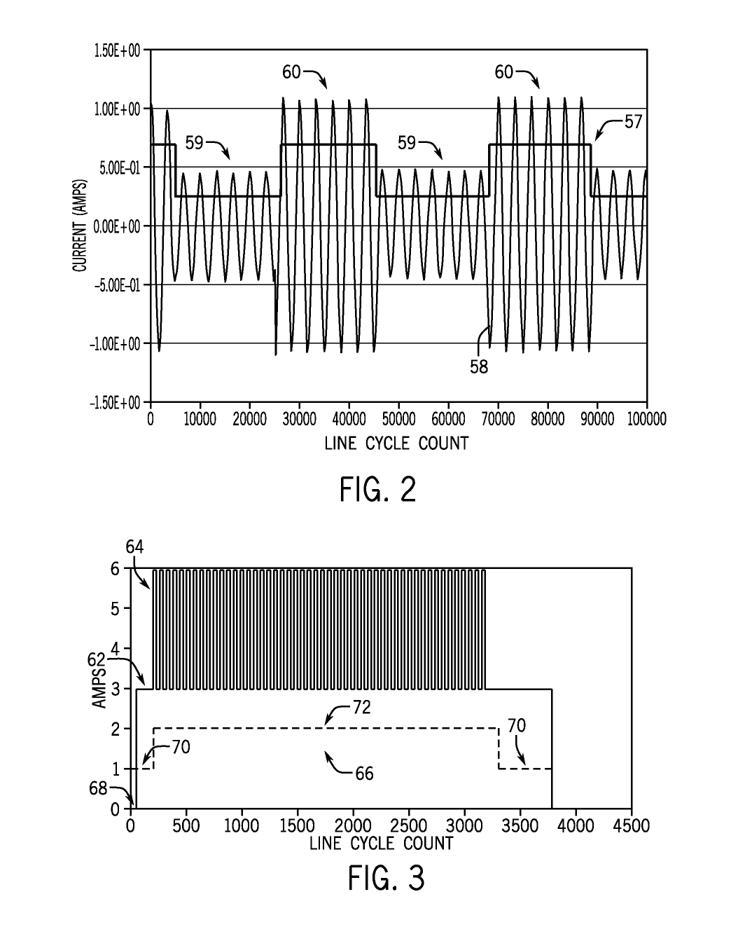

From the current signals received from the current sensors 50, 52, a root mean square (RMS) current value of the capacitive system charging current and ground fault current that is present can be calculated—with this RMS current having a square waveform. An example of the square waveform RMS current 57 that is determined is illustrated in FIG. 2 (for a single phase) in comparison to the oscillographic phase current 58 that is measured by the sensors/CTs 50, 52, with the RMS value being determined at the frequency rate of the line current. In the example provided in FIG. 2, the square waveform of the RMS current 57 is shown to vary periodically at set intervals, with the current having a lower value at periods 58 and an increased (i.e., doubled) value at periods 60, due to the periodic injection of the pulsing current into the power distribution system 10.

In operation, the processor 56 monitors the RMS value of the current over a plurality of cycles (e.g., 60 cycles) for purposes of a identifying a pattern in the RMS value that is indicative of the presence and location of a HRGF in the power distribution system 10—i.e., the presence of a HRGF in either distribution network 24 or distribution network 26. For identifying such a pattern, the RMS current value is input into a “pulse detection algorithm” stored on the processor 56. The pulse detection algorithm stored on the processor 56 functions to threshold the associated RMS values, in order to detect the presence of the injected pulse detection current. It is recognized, however, that other suitable techniques could be employed in the algorithm for detecting the injected pulse detection current, such as Fourier analysis/transform, phase lock loop or other spectral estimation techniques, for example.

Upon input of the RMS current values, the pulse detection algorithm stored on the processor 56 is able to identify the presence and location of a ground fault based on a magnitude of the square waveform and on a pattern in the current data that would be indicative of the presence of a ground fault. More specifically, the algorithm looks for a pattern in the square waveform of the ground RMS current, functioning as an edge detector to identify step changes in the square waveform of the current and examine the duration of any such step changes in order to verify the presence of a ground fault, with the RMS current waveform being compared to predetermined HRGF and pulse thresholds. In operation, the RMS current is sampled asynchronously to when the pulsing circuit 38 is switching, such that some of the sample periods will—by necessity—include some low-current and high-current readings. Back-to-back current samples are measured to verify that they are in a certain range, and current sampling is continued until a step change to a higher or lower value is measured, with further sampling then being performed to verify that a true edge has been measured and not just a spurious reading, as will be explained in greater detail below.

An exemplary square waveform analyzed by the pulse detection algorithm is illustrated in FIG. 3. As shown therein, a first step change in the square waveform current—indicated at 62—may be clearly identified via analysis of the square waveform current, with the step change indicating a change in the current value from 0 amperes to 3 amperes. This first step change is illustrative of a detection of a potential HRGF in the power distribution system 10 (FIG. 1)—which includes a determination that the measured HRGF exceeds a pre-determined HRGF threshold. A second step change in the square waveform current is also visible in FIG. 3—indicated at 64—and, as seen therein, indicates a change in the current value from 3 amperes to 6 amperes. This second step change is illustrative of a detection of a pulsing current being present at the particular location at which the current is being measured/monitored—which includes a determination that the measured HRGF exceeds a pre-determined pulse threshold.

As can be further seen in FIG. 3, in identifying any step changes in the square waveform of the current and examining the duration of any such step changes in order to identify the presence of a HRGF, the pulse detection algorithm outputs one of several “flag” values that are indicative of the state/condition that is present at the particular location at which current is being monitored (i.e., on each distribution network 24, 26 at the motor protection relay 54)—with the trace 66 being illustrative of the flag value. More particularly, the flag value that is output can indicate that no ground current is detected, that ground current near/exceeding a HRGF threshold has been detected, or that a pulsing current has been detected. According to an exemplary embodiment, the output of the pulse detection algorithm is an output flag that can take one of three values—0, 1, or 2. As can be seen in FIG. 3, an output flag with a value of 0—as shown at 68—indicates that no ground current is detected. An output flag with a value of 1—as shown at 70—indicates that ground current near/exceeding a HRGF threshold has been detected (i.e., HRGF Flag=1). An output flag with a value of 2—as shown at 72—indicates that a pulsing current has been detected (i.e., HRGF Flag=1+Pulse Flag=1).

According to one embodiment of the invention, the pulse detection algorithm can also generate an output flag having a fourth value that indicates that the ground current doesn't exceed the HRGF threshold, but a pulsing current is detected. This could occur if the motor protection relay 54 and the motor under load were very close (i.e., short cable distance), as the motor protection relay 54 will only measure charging current downstream therefrom, whereas the HRG device sees the vector sum of all the charging currents connected to it. The fourth flag value may also indicate a malfunction of the pulsing system.

Upon output of a particular flag value, the pulse detection algorithm may monitor a duration/number of consecutive samples at which the flag value is output in order to verify the identification of a particular condition on the respective distribution network 24, 26 being monitored. If a particular flag value is maintained for a particular period of time, i.e., a number of consecutive cycles or current samples, the algorithm determines verifies that a particular condition is present—and is not a “false” condition. Referring to FIG. 3, for example, a flag value of 2 is output for a line cycle count of ˜200 to ˜3,200, which would indicate that a pulsing current is detected at the particular monitoring point for longer than a minimum number of cycles/samples required from verification, and that thus a ground fault is present at that location (i.e., in that distribution network 24, 26).

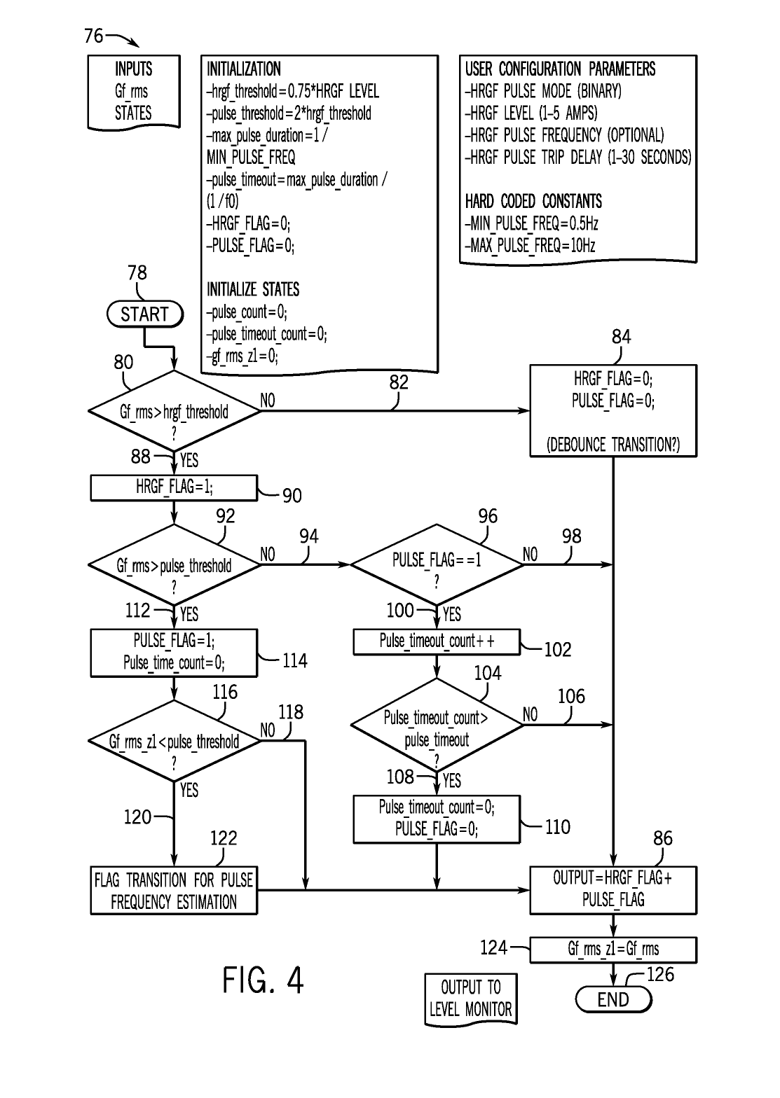

Referring now to FIG. 4, and with continued reference back to FIG. 1, a flowchart illustrating a pulse detection algorithm 76 that may be stored on processor 56 is provided, according to an exemplary embodiment of the invention. The flowchart illustrates a single iteration of the algorithm being performed, but it is recognized that the algorithm runs over a plurality of cycles and functions to collect and compare various current measurements that are received thereby. As shown in FIG. 4, at a start of the algorithm 76, indicated at STEP 78, a series of Initialization Parameters are set for performing the algorithm, including: a HRGF threshold value (e.g., 0.75*HRGF level), a pulse threshold value (e.g., 2*HRGF threshold), a max pulse duration (e.g., 1/minimum pulse frequency), and a pulse timeout value (e.g., maximum pulse duration/(1/f₀). User configuration parameters are also set at STEP 78, including a HRGF level (e.g., 1-5 amps), a HRGF pulse frequency, a HRGF pulse trip delay (1-30 seconds), and hard coded constants of a minimum and maximum pulse current injection frequency (e.g., 0.5 Hz and 10 Hz, respectively) are set. Also at the start of STEP 78, an input is provided to the algorithm of the ground current RMS value (GF_RMS).

The algorithm 76 then continues at STEP 80, where a determination is made as to whether the GF_RMS value is greater than the pre-set HRGF threshold. If it is determined that the GF_RMS value is not greater than the HRGF threshold, as indicated at 82, then the algorithm continues at STEP 84 with the value of a HRGF Flag and Pulse Flag each being set to zero. The algorithm then would continue to STEP 86, with a sum of the HRGF Flag and Pulse Flag values being summed to determine an overall Output Flag value that is output by the algorithm. As can be seen, when the algorithm 76 proceeds from STEP 84 to STEP 86, the Output Flag value would be zero—indicating that no ground fault is present in the power distribution system 10.

Referring back to STEP 80, if it is determined that the GF RMS value is greater than the HRGF threshold, as indicated at 88, then the algorithm continues at STEP 90 where the value of HRGF Flag is set to 1. The algorithm then continues to STEP 92, where a next determination is made as to whether the GF_RMS value is greater than the pre-set Pulse threshold. If it is determined that the GF_RMS value is not greater than the pulse threshold, as indicated at 94, then the algorithm continues at STEP 96 with a determination being made as to whether a Pulse Flag from a previous iteration of the algorithm 76 had been set to have a value of 1. If it is determined that the value of the Pulse Flag from the previous algorithm iteration was not 1 (i.e., Pulse Flag=0), as indicated at 98, then the algorithm proceeds to STEP 86. As can be seen, when the algorithm 76 proceeds to STEP 86 based on a determination at STEP 96 that the Pulse Flag value from the previous iteration was not 1, then the Output Flag value at STEP 86 would be 1, based on the value of the HRGF Flag being 1 (STEP 90). In setting the Output Flag value at 1, it is recognized that a HRGF may be present in the power distribution system 10 and, as such, the pulsing circuit 38 would introduce a pulse current signal generated at desired intervals, e.g., 1 Hz, to provide for confirmation of a HRGF in the system and for localization thereof to a particular distribution network 24, 26.

Referring back now to STEP 96, if it is determined that the value of the Pulse Flag from the previous algorithm iteration was set to 1, as indicated at 100, then the algorithm continues at STEP 102 where the current count of the pulse timeout is increased in value. Upon increasing the pulse timeout count, a determination is then made at STEP 104 as to whether the current pulse timeout count is greater than the pre-set pulse timeout (i.e., set at STEP 78), which as indicated previously is defined as: pulse timeout=maximum pulse duration/(1/f₀).

If it is determined that the current pulse timeout count is not greater than the pulse timeout, as indicated at 106, then the algorithm proceeds to STEP 86. As can be seen, when the algorithm 76 proceeds to STEP 86 based on the determination at STEP 96 that the Pulse Flag value from the previous iteration was set to 1 and based on the determination at STEP 104 that the pulse timeout count is not greater than the pre-set pulse timeout, then the Output Flag value at STEP 86 would be 2, based on the value of the HRGF Flag being 1 (STEP 90) and the value of the Pulse Flag from the previous iteration being maintained at 1.

Conversely, if it is determined at STEP 104 that the current pulse timeout count is greater than the pulse timeout, as indicated at 108, then the algorithm proceeds to STEP 110, where the count of the pulse timeout is reset to zero and a value of the Pulse Flag is set back to zero (as compared to the value of 1 in the previous iteration). Thus, when the algorithm 76 proceeds to STEP 86 based on the determination at STEP 96 that the Pulse Flag value from the previous iteration was set to 1 and based on the determination at STEP 104 that the pulse timeout count is greater than the pre-set pulse timeout, then the Output Flag value at STEP 86 would be 1, based on the value of the HRGF Flag being 1 (STEP 90) and the value of the Pulse Flag being set back to zero (STEP 110).

Referring back now to STEP 92, if it is determined that the GF_RMS value is greater than the pulse threshold, as indicated at 112, then the algorithm continues at STEP 114 with the value of the Pulse Flag for the current iteration of the algorithm being set to 1. Also at STEP 114, the pulse time count is set to zero.

Upon completion of the Pulse Flag being set to 1 and the pulse time count being set to zero, the algorithm 76 continues at STEP 116 by determining whether the ground current RMS value from the previous iteration of the algorithm (GF_RMS_z1) is less than the pre-set Pulse threshold. If it is determined that the GF_RMS_z1 value is not less than the pulse threshold, as indicated at 118, then the algorithm proceeds to STEP 86. When the algorithm 76 proceeds to STEP 86 based on the determination at STEP 116 that the GF_RMS_z1 value is not less than the pulse threshold, then the Output Flag value at STEP 86 would be 2, based on the value of the HRGF Flag being 1 (STEP 90) and the value of the Pulse Flag being 1 (STEP 114).

If it is instead determined at STEP 116 that the GF_RMS_z1 value is less than the pulse threshold, as indicated at 120, then the algorithm proceeds to STEP 122 to flag transition for pulse frequency estimation—with the GF_RMS_z1 value marking the change in state of the pulse signal (positive going) for estimating it's frequency. When the algorithm 76 proceeds to STEP 86 based on the determination at STEP 116 that the GF_RMS_z1 value is less than the pulse threshold, then the Output Flag value at STEP 86 would again be 2, based on the value of the HRGF Flag being 1 (STEP 90) and the value of the Pulse Flag being 1 (STEP 114).

Regardless of the prior determinations made in the iteration of the algorithm presently being performed that lead to the generation of the Output Flag at STEP 86, the algorithm continues from STEP 86 to STEP 124—where upon completion of the present iteration the value of the RMS current value from the previous iteration of the algorithm, GF_RMS_z1, is updated such that it is equal to the most recently determined RMS current value, Gf_RMS, from the present iteration.

Upon updating of the GF_RMS_z1 value, the algorithm 76 then ends at STEP 126. In completing the current iteration of the algorithm at STEP 126, the algorithm causes the processor 56 to output its determination to its associated motor protection relay 54—with the output signifying if a HRGF is present on the distribution network 24, 26 on which the relay is provided. This output to the motor protection relay 54 allows the relay to take any necessary actions that are appropriate in response to the identification of a HRGF being present on the respective distribution network 24, 26.

Based on a series of iterations of the algorithm 76 being performed by the processor 56 of each motor protection relay 54, a pattern in the RMS current value (i.e., based on the Output Flags) can be identified that is indicative of the presence and location of a HRGF in the power distribution system. The Output Flags generated will differ from location to location in the power distribution system 10 based on whether the respective processor 56 of each motor protection relay 54 is sensing the presence of a pulse current at its monitored location. It is therefore possible to localize the HRGF to a particular location based on the Output Flags generated by the algorithm 76 run by the processors 56.

While a specific pulse detection algorithm is described in detail above for identifying and localizing a HRGF in power distribution system 10, it is recognized that variations to the algorithm may be made. That is, variations to the algorithm may be made that do not affect the performance of the algorithm with regard to its functioning to identify and localize a HRGF, and that such variations would still provide a pulse detection algorithm that fits within the scope of the invention.

Accordingly, embodiments of the invention provide a system and method of ground fault detection and localization in high resistance grounded power distribution systems having multiple distribution networks with associated loads. The ground fault detection and localization can be achieved using existing motor protection relays in the power distribution system, without putting unrealistic demands and extra cost on the relay. Instead, it is only required that the motor protection relays be able to perform/analyze measurements accurate enough for an overload function.

A technical contribution for the disclosed method and apparatus is that it provides for a computer implemented technique for detecting and localizing ground faults in a high resistance grounded power distribution system,. The technique is performed by existing motor protection relays and functions to analyze cycle-to-cycle changes in three-phase current signals measured at the relays—with a pulse detection algorithm/technique being performed to identify a pattern in the current.

According to one embodiment of the present invention, a system for locating a ground fault in a high resistance grounded power distribution system includes a pulsing circuit configured to introduce a pulse current into the distribution system and a plurality of current sensors adapted to monitor three-phase current signals present on conductors of the distribution system, wherein the plurality of current sensors are positioned on a number of distribution networks included in the high resistance grounded power distribution system and at a protective device included on each respective distribution network. The system also includes a processor associated with each protective device and operably connected to the current sensors thereat to receive signals from the current sensors for identifying a location of the ground fault in the high resistance grounded power distribution system, wherein the processor associated with each protective device is programmed to receive measurements of the three-phase current signals from the current sensors over a plurality of cycles and identify a pattern of interest in the three-phase current signals across the plurality of cycles in order to detect a ground fault.

According to another embodiment of the present invention, a method for detecting a ground fault in a high resistance grounded power distribution system includes providing a protective device on each of a number of distribution networks in the high resistance grounded power distribution system, each distribution network having a three-phase load connected thereto. The method also includes providing current sensors at each protective device, introducing a pulse current into the high resistance grounded power distribution system via a pulsing circuit, monitoring current at each protective device via the current sensors to collect three-phase current data, and inputting the current data to a processor associated with each protective device to identify and localize a ground fault in the high resistance grounded power distribution system. Identifying and localizing the ground fault further includes determining a root mean square (RMS) current from the collected three-phase current data, identifying step changes in the RMS current across the plurality of cycles to detect pulse current present at the respective protective device, and localizing a ground fault in the high resistance grounded power distribution system to a respective distribution network based on the detection of the pulse current.

According to yet another embodiment of the present invention, a system for detecting a ground fault in a high resistance grounded (HRG) power distribution system includes a protective device connected to each of one or more distribution networks in the HRG power distribution system, the protective device providing monitoring of its associated distribution network and protection to a load connected thereto. The system also includes a plurality of current sensors in operable communication with the protective device to measure three-phase current on the distribution network, the three-phase current comprising a ground current and capacitive system charging current. The protective device includes a processor programmed to receive measurements of the three-phase current signals from the current sensors over a plurality of cycles, determine a root mean square (RMS) current based on the three-phase current signals received from the current sensors, and analyze the RMS current across a plurality of cycles to identify a pattern of interest indicative of a high resistance ground fault.

The present invention has been described in terms of the preferred embodiment, and it is recognized that equivalents, alternatives, and modifications, aside from those expressly stated, are possible and within the scope of the appending claims.

What is claimed is:

1. A system for locating a ground fault in a high resistance grounded power distribution system, the system comprising:
a pulsing circuit configured to introduce a pulse current into the distribution system;
a plurality of current sensors adapted to monitor three-phase current signals present on conductors of the distribution system, wherein the plurality of current sensors are positioned on a number of distribution networks included in the high resistance grounded power distribution system and at a protective device included on each respective distribution network; and
a processor associated with each protective device and operably connected to the current sensors thereat to receive signals from the current sensors for identifying a location of the ground fault in the high resistance grounded power distribution system, wherein the processor associated with each protective device is programmed to:
receive measurements of the three-phase current signals from the current sensors over a plurality of cycles; and
identify a pattern of interest in the three-phase current signals across the plurality of cycles in order to detect a ground fault.

2. The system of claim 1 wherein the processor associated with each protective device is further programmed to determine a root mean square (RMS) current based on the signals received from the current sensors, the RMS current being determined from ground current plus a measure of capacitive system charging current in the three-phase current signals.

3. The system of claim 2 wherein, the RMS current has a square waveform; and
wherein, in identifying the pattern of interest in the signals across the plurality of cycles, the processor associated with each motor protection relay is further programmed to perform a thresholding analysis of the square waveform.

4. The system of claim 3 wherein, in identifying the pattern of interest in the signals across the plurality of cycles, the processor associated with each protective device is further programmed to:
identify step changes in the square waveform across the plurality of cycles; and
compare a magnitude of the square waveform to each of a high resistance ground fault threshold and a pulse threshold.

5. The system of claim 4 wherein the processor associated with each protective device is further programmed to output a ground fault flag based on the identified step changes and the comparison of the square waveform to the high resistance ground fault threshold and pulse threshold, the output ground fault flag having one of:
a first value indicative of no ground current being detected in the respective distribution network;
a second value indicative of a ground current being detected in the respective distribution network exceeding the high resistance ground fault threshold; or
a third value indicative of a pulse current being detected in the respective distribution network.

6. The system of claim 5 wherein the output ground fault flag has a fourth value indicative of a ground current being detected in the respective distribution network that does not exceed the high resistance ground fault threshold, but for which a pulse signal is detected therein.

7. The system of claim 5 wherein, in identifying a pattern of interest, the processor is further programmed to:
compare the output ground fault flag of a current cycle to output ground fault flags from previous cycles;
identify equal ground fault output ground fault flag values across a pre-determined consecutive number of cycles as a pattern of interest indicative of a ground fault.

8. The system of claim 2 wherein the processor is further programmed to digitally filter the RMS current to detect the pattern of the interest in the signals across the plurality of cycles.

9. The system of claim 1 wherein the processor is further programmed to estimate a frequency of the pulse signal.

10. The system of claim 1 wherein the pulse current increases in magnitude of the ground fault present in the electrical power distribution system.

11. A method for detecting a ground fault in a high resistance grounded power distribution system, the method comprising:
providing a protective device on each of a number of distribution networks in the high resistance grounded power distribution system, each distribution network having a three-phase load connected thereto;
providing current sensors at each protective device;
introducing a pulse current into the high resistance grounded power distribution system via a pulsing circuit;
monitoring current at each protective device via the current sensors to collect three-phase current data; and
inputting the current data to a processor associated with each protective device to identify and localize a ground fault in the high resistance grounded power distribution system, wherein identifying and localizing the ground fault comprises:
determining a root mean square (RMS) current from the collected three-phase current data;
identifying step changes in the RMS current across the plurality of cycles to detect pulse current present at the respective protective device; and
localizing a ground fault in the high resistance grounded power distribution system to a respective distribution network based on the detection of the pulse current.

12. The method of claim 11 wherein the RMS current has a square wave current waveform due to the introduced pulse current, with the step changes being identified in the square wave current waveform of the RMS current.

13. The method of claim 12 wherein identifying the ground fault comprises performing one of a thresholding of the square wave current waveform, a Fourier analysis of the square wave current waveform, a phase lock loop analysis of the square wave current waveform, or a spectral estimation on the of the square wave current waveform.

14. The method of claim 11 wherein identifying and localizing the ground fault comprises:
comparing a magnitude of the square wave current waveform to a high resistance ground fault threshold; and
setting a fault flag to a first value if the magnitude of the square wave current waveform does not exceed the high resistance ground fault threshold; and
setting the fault flag to a second value if the magnitude of the square wave current waveform exceeds the high resistance ground fault threshold, indicating that a ground fault is present.

15. The method of claim 14 wherein identifying and localizing the ground fault comprises:
comparing a magnitude of the square wave current waveform to a pulse current threshold;
setting the fault flag to a third value if the magnitude of the square wave current waveform exceeds the pulse current threshold, indicating that the pulse current is present at the respective protective device.

16. A system for detecting a ground fault in a high resistance grounded (HRG) power distribution system, the system comprising:
a protective device connected to each of one or more distribution networks in the HRG power distribution system, the protective device providing monitoring of its associated distribution network and protection to a load connected thereto; and
a plurality of current sensors in operable communication with the protective device to measure three-phase current on the distribution network, the three-phase current comprising a ground current and capacitive system charging current;
wherein the protective device includes a processor programmed to:
receive measurements of the three-phase current signals from the current sensors over a plurality of cycles;
determine a root mean square (RMS) current based on the three-phase current signals received from the current sensors; and
analyze the RMS current across a plurality of cycles to identify a pattern of interest indicative of a high resistance ground fault.

17. The system of claim 16 wherein the RMS current comprises a square waveform, and wherein the processor is further programmed to compare a magnitude of the square waveform to each of a high resistance ground fault threshold and a pulse threshold.

18. The system of claim 17 wherein, if the magnitude of the square waveform exceeds the high resistance ground fault threshold, the processor is further programmed to:
cause a test signal generator to introduce a pulsing signal into the HRG power distribution system; and
detect step changes in the magnitude of the square waveform indicative of the presence of the pulsing signal if present.

19. The system of claim 18 wherein the processor is further programmed to:
monitor the step changes in the magnitude of the square waveform across the plurality of cycles; and
identify a square waveform having a magnitude exceeding the pulse threshold, across a pre-determined consecutive number of cycles, as a pattern of interest indicative of a ground fault.

20. The system of claim 17 wherein the processor is further programmed to output a ground fault flag based on the identified step changes and the comparison of the square waveform to the high resistance ground fault threshold and pulse threshold, the output ground fault flag having one of:
a first value indicative of no ground current being detected in the respective distribution network;
a second value indicative of a ground current being detected in the respective distribution network exceeding the high resistance ground fault threshold;
a third value indicative of the pulse signal being detected in the respective distribution network; or
a fourth value indicative of either a HRG malfunction or an improper setting of the high resistance ground fault threshold at the protective device.
